(19) United States
(12) Patent Application Publication
(10) Pub. No.: US 2026/0047201 A1
(43) Pub. Date: Feb. 12, 2026

(54) CMOS DEVICE AND METHOD FOR FABRICATING SAME

(71) Applicant: Hangzhou HFC Semiconductor Co., Hangzhou (CN)

(72) Inventors: Tian GAO, Hangzhou (CN); Tsung-Yu YU, Hangzhou (CN); Zuoqiang FAN, Hangzhou (CN); Yihua SHEN, Hangzhou (CN)

(21) Appl. No.: 18/891,892

(22) Filed: Sep. 20, 2024

(30) Foreign Application Priority Data
Aug. 12, 2024 (CN) 202411095538.5

(51) Int. Cl. H01L 21/84; H01L 27/12

(52) U.S. Cl. CPC H10D 86/01; H10D 86/201

(57) ABSTRACT

A CMOS device and a method for fabricating the device are disclosed. In the method, an in-situ etch-back process is performed to form trenches in PFET regions, which extends through a partial thickness of the PFET region and exposes side wall of the STI structure. Subsequently, an in-situ epitaxial growth process is performed to form channel layer in the trenches. In this process, the side walls of the STI structures can block lateral growth of the channel layer in the trenches, overcoming the problem that the resulting channel layer may have a smaller thickness formed above edge areas of the PFET regions than formed above central areas thereof. In addition, before the channel layer is formed, the substrate is subjected to an in-situ pre-baking process, which removes moisture and contaminants in the trenches.

### CROSS-REFERENCE TO RELATED APPLICATION

This application claims the priority of Chinese patent application number 202411095538.5, filed on Aug. 12, 2024 and entitled “CMOS DEVICE AND METHOD FOR FABRICATING SAME”, the entire contents of which are incorporated herein by reference.

### TECHNICAL FIELD

The present invention relates to the field of semiconductor technology and, in particular, to a complementary metal-oxide-semiconductor (CMOS) device and a method for fabricating the device.

### BACKGROUND

With increasing shrinkage of devices, the carrier mobility of traditional silicon channels is gradually approaching the limit of ability to meet the ever-growing demands for higher device performance. To address this, as shown in FIG. 1, epitaxial channel layer 12, e.g., silicon germanium (SiGe) layer, is usually introduced on PFET regions 11 of a substrate 10. However, during epitaxial growth of the channel layer 12, as crystals tend to grow at different rates in various crystallographic directions, lateral epitaxial growth may occur, leading to the resulting channel layer 12 being thicker in the center and thinner at the edges, or even having different thicknesses of channel layer in low-feature-density (LFD) II and high-feature-density (HFD) I areas. Consequently, channel layer 12 on PFET regions having different channel widths may have different thicknesses. That is, the thickness of the channel layer 12 may be not uniform. Such non-uniform thicknesses not only degrade the quality of the channel layer, but also affect the reliability and performance of subsequently formed features. Further, carbon and oxygen contaminants on the surfaces of the PFET regions 11 may affect the growth of the channel layer 12 and lead to the formation of defects.

### SUMMARY OF THE INVENTION

It is an object of the present invention to provide a CMOS device and a method for fabricating the device, which allows a channel layer to be formed with increased thickness uniformity and reduce or totally remove carbon and oxygen contaminants.

The above object is attained by a method for fabricating a CMOS device provided in the present invention, which comprises: providing a substrate comprising a plurality of PFET regions and a plurality of NFET regions, wherein the NFET region is adjacent to the PFET region and wherein a shallow trench isolation (STI) structure is formed between adjacent PFET region and NFET region; forming a patterned mask layer on the substrate, which covers the NFET regions and exposes the PFET regions; with the patterned mask layer serving as a mask, performing an in-situ etch-back process on the PFET regions to form trenches therein, which extends through a portion of a thickness of the PFET regions and exposes a portion of a side wall of the STI structure; performing an in-situ pre-baking process on the substrate; performing an in-situ epitaxial growth process to form channel layer in the trenches, a top surface of the channel layer is flush with top surfaces of the STI structures; and removing the patterned mask layer.

On the basis of the same inventive concept, the present invention also provides a CMOS device comprising: a substrate comprising a plurality of PFET regions and a plurality of NFET regions, wherein the NFET region is adjacent to the PFET region, wherein a shallow trench isolation (STI) structure is formed between adjacent PFET region and NFET region, the PFET regions formed therein with trenches which extends through a portion of a thickness of the PFET regions and exposes a portion of a side wall of the STI structures; and a channel layer formed in the trenches, wherein a top surface of the channel layer is flush with top surfaces of the STI structures.

In the CMOS device and method of the present invention, an in-situ etch-back process is carried out to form trenches in PFET regions, each trench extending through a portion of a thickness of the PFET region and exposes a portion of a side wall of STI structure. Subsequently, an in-situ epitaxial growth process is performed to form a channel layer in the trenches. In this process, the side walls of the STI structures can block lateral growth of the channel layer in the trenches, overcoming the problem that the resulting channel layer may have a smaller thickness formed above edge areas of the PFET regions than formed above central areas thereof. Therefore, the channel layer has improved thickness uniformity. In addition, before the channel layer is formed, the substrate is subjected to an in-situ pre-baking process, which removes moisture and contaminants in the trenches. Since the in-situ etch-back process performed on the PFET regions, the in-situ pre-baking process and the in-situ epitaxial growth process are all in-situ processes, the presence of carbon and oxygen contaminants in the trenches can be reduced to a low level which enables the resulting channel layer to have improved quality.

### BRIEF DESCRIPTION OF THE DRAWINGS

FIG. 1 shows SEM images of conventional channel layer.

FIG. 2 is a flowchart of a method of forming a CMOS device according to an embodiment of the present invention.

FIG. 3 schematically illustrates a structure resulting from forming PFET and NFET regions in the method according to an embodiment of the present invention.

FIG. 4 schematically illustrates a structure resulting from forming a mask layer in the method according to an embodiment of the present invention.

FIG. 5 schematically illustrates a structure resulting from forming a patterned mask layer in the method according to an embodiment of the present invention.

FIG. 6 schematically illustrates a structure resulting from the formation of a native oxide layer in the method according to an embodiment of the present invention.

FIG. 7 schematically illustrates a structure resulting from forming trenches in the method according to an embodiment of the present invention.

FIG. 8 schematically illustrates a structure resulting from forming channel layer in the method according to an embodiment of the present invention.

FIG. 9 schematically illustrates a structure resulting from removing the patterned mask layer in the method according to an embodiment of the present invention.

FIG. 10 schematically illustrates a structure resulting from forming a gate dielectric layer in the method according to an embodiment of the present invention.

FIG. 11 shows SEM images of a CMOS device according to an embodiment of the present invention.

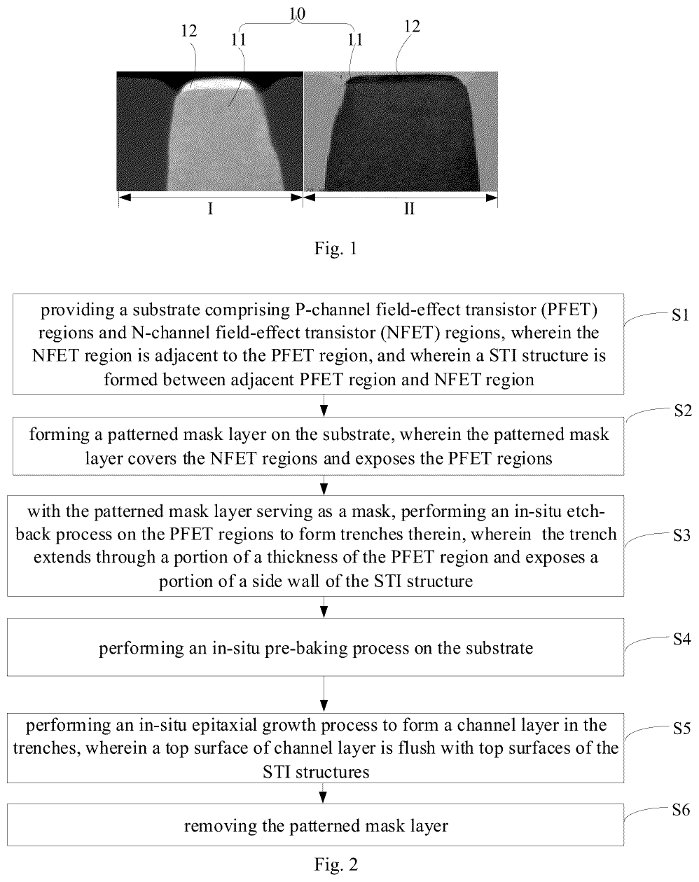

### LIST OF REFERENCE NUMERALS

10, substrate; 11, PFET region; 12, channel layer; 100, substrate; 100A, PFET region; 100B, NFET region; 101, bottom silicon layer; 102, insulator layer; 103, top silicon layer; 110, STI structure; 120, mask layer; 120A, patterned mask layer; 130, native oxide layer; 140, trench; 140A, corner; 150, channel layer; 160, gate dielectric layer.

### DETAILED DESCRIPTION

CMOS devices and method proposed in the present invention will be described in greater detail below with reference to the accompanying drawings, which illustrate specific embodiments thereof. From the following description, advantages and features of the invention will become apparent. Note that the figures are provided in a very simplified form not necessarily drawn to exact scale for the only purpose of helping to explain the disclosed embodiments in a more convenient and clearer way.

As used herein, the singular forms “a”, “an” and “the” include plural referents. The term “or” is generally employed in the sense of “and/or”, “several” is generally employed in the sense of “at least one” and “at least two” is generally employed in the sense of “two or more”. In addition, the terms “first”, “second” and “third” are intended only for illustration and are not to be construed as denoting or implying relative importance, or as implicitly indicating the numerical number of the referenced items. Accordingly, defining an item with “first”, “second” or “third” is an explicit or implicit indication of the presence of one or at least two such items.

FIG. 2 is a flowchart of a method of forming a complementary metal-oxide-semiconductor (CMOS) device according to an embodiment of the present invention. As shown in FIG. 2, the method includes: in step S1, providing a substrate including PFET regions and NFET regions, the PFET regions and NFET regions are adjacent and separated by STI structures; in step S2, forming a patterned mask layer on the substrate, which covers the NFET regions and exposes the PFET regions; in step S3, with the patterned mask layer serving as a mask, performing an in-situ etch-back process on the PFET regions to form trenches therein, the trench extends through a portion of a thickness of the PFET region and exposes a portion of side wall of the STI structures; in step S4, subjecting the substrate to an in-situ pre-baking process; in step S5, performing an in-situ epitaxial growth process to form a channel layer in the trenches, top surfaces of trenches are flush with top surfaces of the STI structures; and in step S6, removing the patterned mask layer.

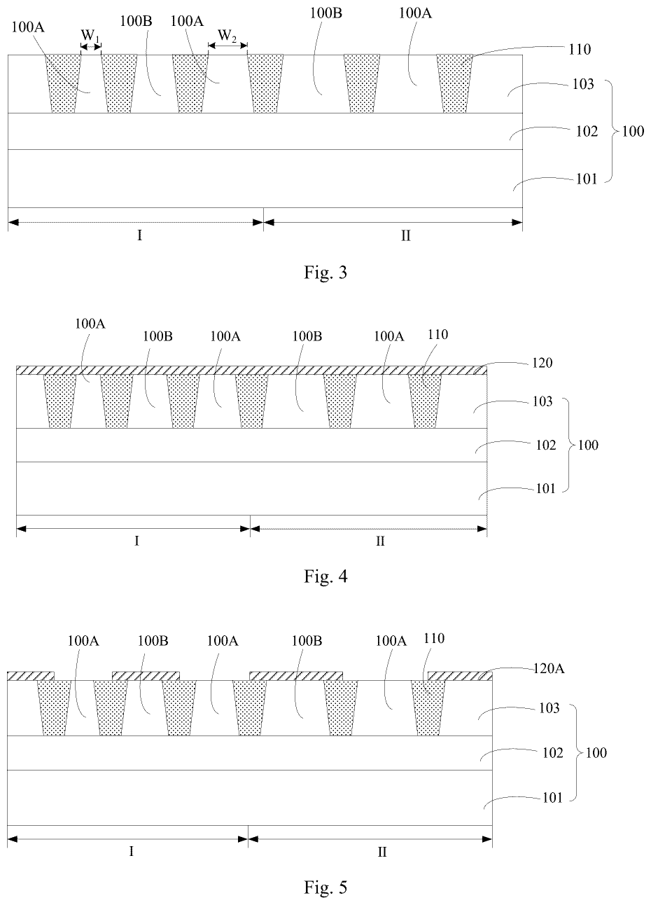

The method will be described in greater detail below with reference to FIGS. 3 to 10, which illustrate specific embodiments of the present invention.

FIG. 3 schematically illustrates a structure resulting from forming PFET and NFET regions in the method according to an embodiment of the present invention. First of all, referring to FIG. 3, in step S1, a substrate 100 is provided, which include PFET regions 100A and NFET regions 100B, the PFET regions 100A and NFET regions 100B are adjacent and separated by shallow trench isolation (STI) structures 110. P-channel field-effect transistors (PFETs) are to be formed in the PFET regions 100A, and N-channel field-effect transistors (NFETs) are to be formed in the NFET regions 100B. Moreover, well regions are formed in the PFET regions 100A and the NFET regions 100B. In order to avoid unnecessarily obscuring the invention, description and illustration of the well regions are omitted herein.

In one embodiment, the substrate 100 may be a silicon-on-insulator (SOI) substrate consisting of a bottom silicon layer 101, an insulator layer 102 and a top silicon layer 103, which are stacked from the bottom upwards. The STI structures 110 are formed in the top silicon layer 103, optionally, the STI structures 110 extend through the top silicon layer 103 and isolate the top silicon layer 103 into the PFET regions 100A and NFET regions 100B. Additionally, top surfaces of the STI structures 110, top surfaces of the PFET regions 100A and top surfaces of the NFET regions 100B are flush with one another. Each STI structure 110 may comprise a cross-section in the shape of a rectangle or inverted trapezoid. The following description is set forth in the context of each STI structure 110 comprising an inverted trapezoidal cross-section, as an example.

In addition, as shown in FIG. 3, the substrate 100 comprises a high-feature-density (HFD) area I and a low-feature-density (LFD) area II. The LFD area II is a region with a low feature density, and the HFD area I is a region with a high feature density.

Further, in each of the HFD area I and the LFD area II of the substrate 100, there are a plurality (three or more) of the PFET regions 100A and a plurality (three or more) of the NFET regions 100B. At least two of the PFET regions 100A in the LFD area II have different channel widths. For example, one of the PFET regions 100A in the LFD area II may have a narrow channel width, and another one of the PFET regions 100A may have a wide channel width greater than the narrow channel width.

At least two of the PFET regions 100A in the HFD area I have different channel widths. For example, as shown in FIG. 3, in the HFD area I, one of the PFET regions 100A has a narrow channel width W1, and another one of the PFET regions 100A has a wide channel width W2 greater than the narrow channel width W1.

The PFET regions 100A in the HFD area I are present at a higher density than the PFET regions 100A in the LFD area II. Moreover, the NFET regions 100B in the HFD area I are present at a higher density than the NFET regions 100B in the LFD area II.

FIG. 4 schematically illustrates a structure resulting from forming a mask layer in the method according to an embodiment of the present invention. FIG. 5 schematically illustrates a structure resulting from forming a patterned mask layer in the method according to an embodiment of the present invention. As shown in FIG. 5, in step S2, a patterned mask layer 120A is formed on the substrate 100, which covers the NFET regions 100B and exposes the PFET regions 100A. In further embodiments, the patterned mask layer 120A may also expose portions of the STI structures 110 proximate the PFET regions 100A and may also cover portions of the STI structures 110 proximate the NFET regions 100B.

In particular, the patterned mask layer 120A may be formed on the substrate 100 using a process including, as shown in FIG. 4, forming a mask layer 120 which covers the substrate 100. The mask layer 120 may be a silicon oxide layer formed using any technique well known to those skilled in the art, such as wet oxidation. The process may further include forming a patterned photoresist layer (not shown) on the mask layer 120, which exposes the mask layer 120 above the PFET regions 100A. As shown in FIG. 5, the process may further include, etching the mask layer 120, with the patterned photoresist layer serving as a mask, to remove the mask layer 120 above the PFET regions 100A, thereby forming the patterned mask layer 120A. The patterned photoresist layer may be then stripped away.

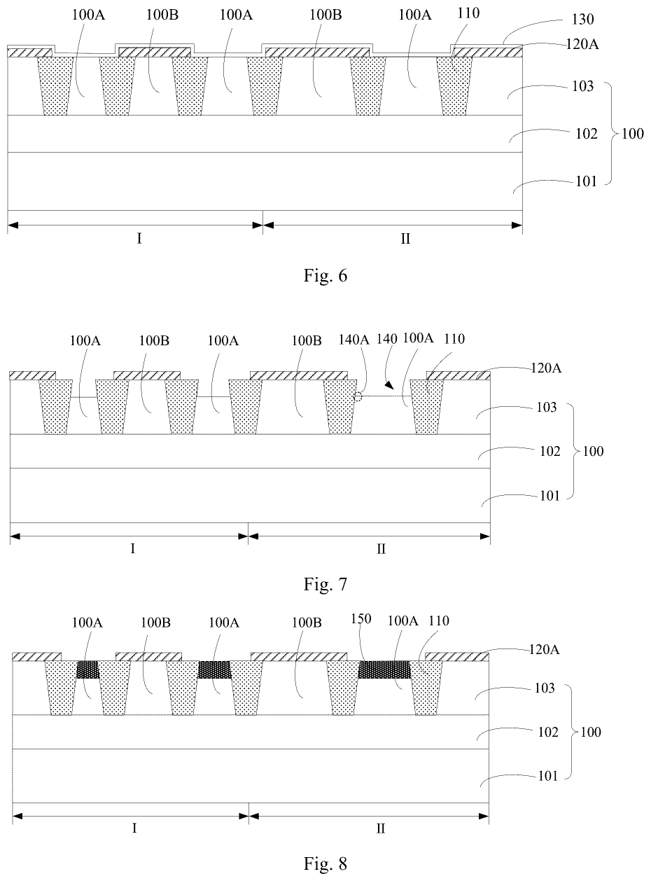

FIG. 6 schematically illustrates a structure resulting from the formation of a native oxide layer in the method according to an embodiment of the present invention. As shown in FIG. 6, the exposed patterned mask layer 120A and the PFET regions 100A are placed in an environment containing oxygen and moisture, and a native oxide layer 130 forms on the surface of the patterned mask layer 120A and the PFET regions 100A.

After that, an in-situ plasma cleaning process is performed to remove the native oxide layer 130, as well as carbon (originating from the atmosphere and from volatilization of organic substances from the photoresist layer) and oxygen contaminants on the surface of the patterned mask layer 120A and the PFET regions 100A. The in-situ plasma cleaning process may use a cleaning gas including nitrogen trifluoride (NF₃) and ammonia (NH₃).

In particular, the in-situ plasma cleaning process may include placing the substrate 100 in a reaction chamber and exciting the cleaning gas (NF₃ and NH₃) into plasma with a high-frequency electric field, microwaves or the like in the reaction chamber. Once the cleaning gas (NF₃ and NH₃) is introduced into a plasma-generating zone, it is decomposed to produce reactive free radicals, which chemically react with the native oxide layer 130, thus converting the native oxide layer 130 into volatile gaseous or solid products. These products are then discharged from the reaction chamber along with the carbon and oxygen contaminants on the surface of the patterned mask layer 120A and the PFET regions 100A.

FIG. 7 schematically illustrates a structure resulting from forming trenches in the method according to an embodiment of the present invention. As shown in FIG. 7, in step S3, with the patterned mask layer 120A as a mask, an in-situ etch-back process is performed on the PFET regions 100A to form trenches 140. The trench 140 extends through a portion of a thickness of the PFET region 100A and exposes portions of side wall of the STI structures 110. In particular, the in-situ etch-back process performed on the PFET regions 100A may use hydrogen chloride (HCl) as an etchant gas, which shows high etch selectivity between the PFET regions 100A and the STI structures 110, thus reducing or avoiding damage to the STI structures 110.

Optionally, during the in-situ etching process of the PFET region 100A, etching the PFET regions 100A along the sidewalls of the STI structures 110, thereby forming trenches 140. The trenches 140 serve as a window for the channel layer 150 to be formed subsequently.

Optionally, the trenches 140 comprise a rectangular cross-sectional shape, which can help suppress subsequent lateral growth of the channel layer 150. Alternatively, the trenches 140 may comprise a trapezoidal cross-sectional shape.

It is noted that the in-situ etch-back process is performed on all the PFET regions 100A in both the HFD area I and the LFD area II to form a trench 140 in each PFET region 100A. The trench 140 in each PFET region 100A has an equal depth optionally of 5 nm to 15 nm. In addition, since each of the HFD area I and the LFD area II has PFET regions 100A with different channel widths, the trenches 140 formed in the PFET regions 100A also have different widths.

The in-situ etch-back process may be performed on the PFET regions 100A in the same reaction chamber as the in-situ plasma cleaning process. Next, in step S4, the substrate 100 is subjected to an in-situ pre-baking process using a gas containing hydrogen. The in-situ pre-baking process performed on the substrate 100 can remove moisture and unwanted substances on the substrate 100, in particular moisture and unwanted substances (carbon and oxygen contaminants) remaining in the trenches 140.

It is noted that the in-situ pre-baking process should not be performed at a temperature that is too high or too low. An excessively high temperature used in the in-situ pre-baking process tends to induce thermal diffusion within the substrate 100 and hence uncontrolled reflow of silicon atoms in the trenches 140, which may distort the contours of the trenches 140. Consequently, corners 140A of the trenches 140 may be rounded, and silicon damage may occur in the substrate 100 at the corners 140A of the trenches 140, and the channel layer 150 subsequently formed in the trenches 140 may have thinner edge areas. Moreover, an excessively high temperature used in the in-situ pre-baking process may also disturb the crystal lattice in the trenches 140, degrading the quality of the channel layer 150 subsequently formed in the trenches 140. On the other hand, an excessively low temperature used in the in-situ pre-baking process tends to lead to incomplete removal of moisture or unwanted substances in the trenches 140. For these reasons, in one embodiment, the in-situ pre-baking process is performed at a temperature of 750° C. to 850° C., such as, for example, 800° C.

Further, the in-situ plasma cleaning process conducted in the above described step and the subsequent in-situ etch-back process to form the trenches 140 can additionally reduce the presence of unwanted substances in the resulting trenches 140, allows the in-situ pre-baking process to be carried out at a relatively low temperature, such as 750° C. to 850° C. In this way, removal of moisture and unwanted substances in the trenches 140 can be ensured, while avoiding reflow of silicon atoms in the trenches 140 and rounding of the corners 140A of the resulting trenches 140. As a result, silicon damage in the substrate 100 at the corners 140A of the trenches 140 can be avoided, helping in avoiding the subsequently formed channel layer 150 from having thinner edge areas.

FIG. 8 schematically illustrates a structure resulting from forming channel layer in the method according to an embodiment of the present invention. As shown in FIG. 8, in step S5, an in-situ epitaxial growth process is carried out to form channel layer 150 in the trenches 140, top surface of the channel layer 150 is flush with the top surfaces of the STI structures 110. The channel layer 150 has a thickness of 5 nm to 15 nm. That is, the thickness of the channel layer 150 may be equal to the depth of the trench 140.

Specifically, the in-situ epitaxial growth process may be a selective epitaxial growth process, such as a molecular-beam epitaxy (MBE) process or a reduced pressure chemical vapor deposition (RPCVD), which enables the channel layer 150 to form only on the surface of the PFET regions 100A. The channel layer 150 may be a silicon germanium (SiGe) layer.

In one embodiment, in order to form the channel layer 150, the in-situ epitaxial growth process may be performed at a temperature of 600° C. to 700° C. using a process gas including a silicon source gas, a germanium source gas, an etchant gas and a dopant source gas. The dopant source gas is used to provide dopant ions and may be, for example, borane (BH₃), diborane (B₂H₆) or boron trichloride (BCl₃). The silicon source gas may be silane (SiH₄), disilane (Si₂H₆), trisilane (Si₃H₈) or dichlorosilane (SiH₂Cl₂). The germanium source gas may be germane (GeH₄). The etchant gas may be hydrogen chloride (HCl) and used to enhance selectivity of deposition, so as to form the channel layer 150 in the trenches 140. The process gas for forming the channel layer 150 may further include hydrogen serving as a carrier gas for the etchant gas.

Optionally, the in-situ plasma cleaning process, the in-situ etch-back process performed on the PFET regions 100A, the in-situ pre-baking process and the in-situ epitaxial growth process are carried out in the same reaction chamber. That is, the in-situ plasma cleaning process, the in-situ etch-back process performed on the PFET regions 100A, the in-situ pre-baking process and the in-situ epitaxial growth process are accomplished using the same equipment, such as MBE or RPCVD equipment. This can reduce the presence of carbon and oxygen contaminants in the trenches 140 to a low level which enables the resulting channel layer 150 to have improved quality.

In one embodiment, the channels in the PFET regions 100A are oriented in the <110> crystallographic direction, which imparts higher hole mobility to the channels in the PFET regions 100A. During the formation of the channel layer 150, due to anisotropy of the in-situ epitaxial growth process, the channel layer 150 grows thickness-wise (i.e., toward the <100> crystallographic plane) at a higher rate than widthwise (or laterally, i.e., toward the <110> crystallographic plane). Moreover, since the channel layer 150 is formed in the trenches 140 that are delimited by side walls of the STI structures 110, during the epitaxial growth of the channel layer 150, the STI structures 110 can block their lateral growth, avoiding the resulting channel layer 150 from having a smaller thickness formed above edge areas of the PFET regions 100A (proximate the STI structures) than formed above central areas of the PFET regions 100A. As a result, the resulting channel layer 150 formed on the PFET regions 100A, whether having different channel widths or arranged at different densities, all have more uniform thicknesses. More specifically, since HFD area I and the LFD area II each contain PFET regions 100A having different channel widths, the channel layer 150 formed on the PFET regions 100A also have different channel widths. Moreover, the channel layer 150 formed on the PFET regions 100A in the HFD area I are present at a different density than the channel layer 150 formed on the PFET regions 100A in the LFD area II. Despite these, the thicknesses of the channel layer 150 formed on the PFET regions 100A in the HFD area I are comparable to the thicknesses of the channel layer 150 formed on the PFET regions 100A in the LFD area II. That is, there are no significant thickness differences between the channel layer 150 formed on the PFET regions 100A that have different channel widths and are arranged at different densities. This can prevent the thickness loading effect.

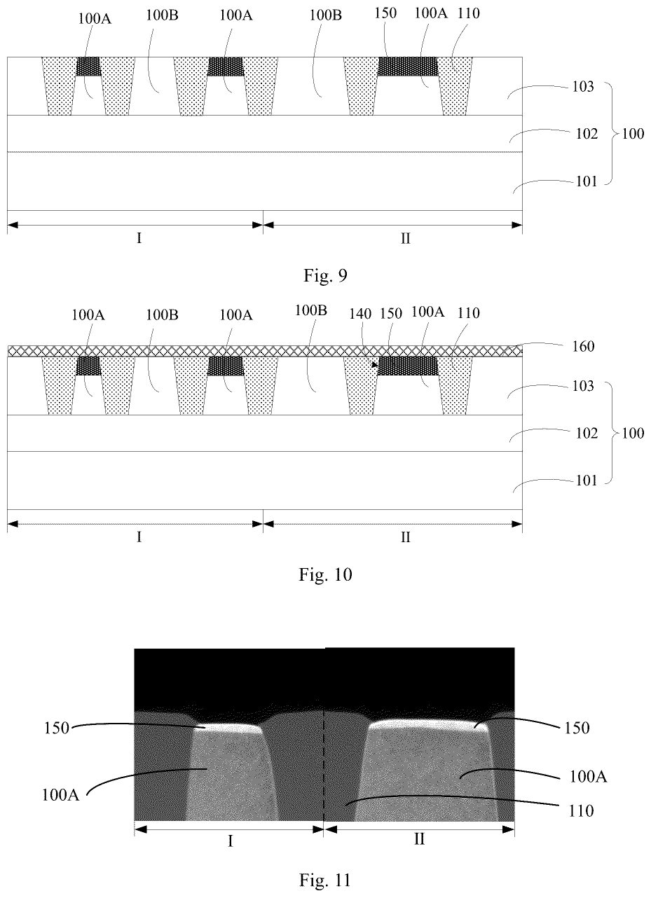

FIG. 9 schematically illustrates a structure resulting from removing the patterned mask layer in the method according to an embodiment of the present invention. As shown in FIG. 9, in step S6, the patterned mask layer 120A is removed. Optionally, the patterned mask layer 120A is removed using a wet etching process using a solution containing hydrofluoric acid, which exhibits high etch selectivity between the patterned mask layer 120A and the channel layer 150, thereby avoiding the process from causing damage to the channel layer 150.

FIG. 10 schematically illustrates a structure resulting from forming a gate dielectric layer in the method according to an embodiment of the present invention. As shown in FIG. 10, a gate dielectric layer 160 is formed, which covers the channel layer 150, the STI structures 110, the PFET regions 100A and the NFET regions 100B. The gate dielectric layer 160 may be silicon oxide and is preferably formed by thermal oxidation. Compared with other technique, thermal oxidation allows the resulting gate dielectric layer 160 to exhibit better interfacial compatibility with the channel layer 150.

In embodiments of the present invention, there is also provided a complementary metal-oxide-semiconductor (CMOS) device. As shown in FIG. 10, the CMOS device comprises: a substrate 100 comprising PFET regions 100A and NFET regions 100B adjacent to the PFET regions 100A, the STI structures 110 are formed between the PFET regions 100A and the NFET regions 100B, the PFET regions 100A formed therein with trenches 140 extending through a portion of thickness of the PFET region 100A and exposing a portion of side wall of the STI structure 110; and a channel layer 150 formed in the trenches 140, the channel layer 150 having top surface flush with top surfaces of the STI structures 110.

Specifically, as shown in FIG. 10, the substrate 100 comprises a high-feature-density (HFD) area I and a low-feature-density (LFD) area II. In each of the HFD area I and the LFD area II, a plurality (three or more) of the PFET regions 100A and a plurality (three or more) of the NFET regions 100B are formed in the substrate 100. The PFET regions 100A in the HFD area I are present at a higher density than the PFET regions 100A in the LFD area II. Moreover, the NFET regions 100B in the HFD area I are present at a higher density than the NFET regions 100B in the LFD area II. At least two of the PFET regions 100A in the HFD area I have different channel widths. For example, in the HFD area I, one of the PFET regions 100A has a narrow channel width, and another one of the PFET regions 100A has a wide channel width greater than the narrow channel width.

At least two of the PFET regions 100A in the LFD area II have different channel widths. For example, in the LFD area II, one of the PFET regions 100A has a narrow channel width, and another one of the PFET regions 100A has a wide channel width greater than the narrow channel width.

FIG. 11 shows SEM images of the CMOS device according to an embodiment of the present invention. As shown in FIG. 11, the thickness of the channel layer 150 located above the edge of the PFET region 100A is essentially the same as the thickness of the channel layer 150 located above the center of the PFET region 100A. Moreover, the thickness of the channel layer 150 on the PFET region 100A in the HFD area I is the same as that on the PFET region 100A in the LFD area II. In other words, the thickness of the channel layer 150 is uniform above PFET regions 100A with different densities and channel widths, thereby improving the thickness uniformity of the channel layer 150. Furthermore, as shown in FIG. 10, the CMOS device further includes a gate dielectric layer 160 covering the channel layer 150, the STI structures 110, the PFET regions 100A and the NFET regions 100B.

In summary, in embodiments of the present invention, there are provided a CMOS device and a method for fabricating the device, in which an in-situ etch-back process is carried out to form trenches in PFET regions, which extend through portions of the thickness of the PFET regions and expose portions of side walls of STI structures. Subsequently, an in-situ epitaxial growth process is performed to form channel layer in the trenches. In this process, the side walls of the STI structures can block lateral growth of the channel layer in the trenches, overcoming the problem that the resulting channel layer may have a smaller thickness formed above edge areas of the PFET regions than formed above central areas of the PFET regions. Therefore, the channel layer has improved thickness uniformity. In addition, before the channel layer is formed, the substrate is subjected to an in-situ pre-baking process, which removes moisture and contaminants in the trenches. Since the in-situ etch-back process performed on the PFET regions, the in-situ pre-baking process and the in-situ epitaxial growth process are all in-situ processes, the presence of carbon and oxygen contaminants in the trenches can be reduced to a low level which enables the resulting channel layer to have improved quality.

The description presented above is merely that of some preferred embodiments of the present invention and is not intended to limit the scope thereof in any sense. Any and all changes and modifications made by those of ordinary skill in the art based on the above teachings fall within the scope of the invention. Further, it is recognized that while the invention has been described above with reference to preferred embodiments thereof, it is not intended to be limited to these embodiments. In light of the above teachings, any person familiar with the art may make many possible modifications and variations to the disclosed embodiments or adapt them into equivalent embodiments, without departing from the scope of the invention. Accordingly, it is intended that any and all simple variations, equivalent changes and modifications made to the foregoing embodiments based on the substantive disclosure of the invention without departing from the scope thereof fall within this scope.

What is claimed is:

1. A method for fabricating a complementary metal-oxide-semiconductor (CMOS) device, comprising:
providing a substrate comprising a plurality of P-channel field-effect transistor (PFET) regions and a plurality of N-channel field-effect transistor (NFET) regions, wherein the NFET region is adjacent to the PFET region, and wherein a shallow trench isolation (STI) structure is formed between adjacent PFET region and NFET region;
forming a patterned mask layer on the substrate, wherein the patterned mask layer covers the NFET regions and exposes the PFET regions;
with the patterned mask layer serving as a mask, performing an in-situ etch-back process on the PFET regions to form trenches therein, wherein the trench extends through a portion of a thickness of the PFET region and exposes a portion of a side wall of the STI structure;
performing an in-situ pre-baking process on the substrate;
performing an in-situ epitaxial growth process to form a channel layer in the trenches, wherein a top surface of channel layer is flush with top surfaces of the STI structures; and
removing the patterned mask layer.

2. The method of claim 1, wherein the in-situ etch-back process performed on the PFET regions uses an etchant gas comprising hydrogen chloride.

3. The method of claim 1, wherein the in-situ pre-baking process uses a gas comprising hydrogen and is performed at a temperature of 750° C. to 850° C.

4. The method of claim 1, wherein the trench has a depth of 5 nm to 15 nm.

5. The method of claim 1, wherein: after the patterned mask layer is formed and before the in-situ etch-back process is performed on the PFET regions, a native oxide layer forms on a surface of the patterned mask layer and surfaces of the PFET regions; and
before the in-situ etch-back process is performed on the PFET regions, the method further comprises: performing an in-situ plasma cleaning process to remove the native oxide layer.

6. The method of claim 5, wherein the in-situ plasma cleaning process uses a cleaning gas comprising nitrogen trifluoride and ammonia.

7. The method of claim 5, wherein the in-situ plasma cleaning process, the in-situ etch-back process performed on the PFET regions, the in-situ pre-baking process and the in-situ epitaxial growth process are carried out in a same reaction chamber.

8. The method of claim 1, wherein the channel layer is a silicon germanium layer.

9. The method of claim 1, wherein the substrate comprises a high-feature-density (HFD) area and a low-feature-density (LFD) area, wherein each of the HFD area and the LFD area comprises a plurality of PFET regions and a plurality of NFET regions, wherein at least two of the PFET regions in the HFD area have different channel widths, and at least two of the PFET regions in the LFD area have different channel widths, and wherein a portion of the channel layer formed on the PFET region in the HFD area has a same thickness as a portion of the channel layer formed on the PFET region in the LFD area.

10. A complementary metal-oxide-semiconductor (CMOS) device, comprising:
a substrate comprising a plurality of P-channel field-effect transistor (PFET) regions and a plurality of N-channel field-effect transistor (NFET) regions, wherein the NFET region is adjacent to the PFET region, wherein a shallow trench isolation (STI) structure is formed between adjacent PFET region and NFET region, wherein each PFET region is formed therein with a trench which extends through a portion of a thickness of the PFET region and exposes a portion of a side wall of the STI structure; and
a channel layer formed in the trenches, wherein a top surface of the channel layer is flush with top surfaces of the STI structures.

11. The CMOS device of claim 10, wherein the trench has a depth of 5 nm to 15 nm.

12. The CMOS device of claim 10, wherein the channel layer is a silicon germanium layer.

13. The CMOS device of claim 10, wherein the substrate comprises a high-feature-density (HFD) area and a low-feature-density (LFD) area, wherein each of the HFD area and the LFD area comprises a plurality of PFET regions and a plurality of NFET regions, wherein at least two of the PFET regions in the HFD area have different channel widths, and at least two of the PFET regions in the LFD area have different channel widths, and wherein a portion of the channel layer formed on the PFET region in the HFD area has a same thickness as a portion of the channel layer formed on the PFET region in the LFD area.
